(19) United States
(12) Patent Application Publication
(10) Pub. No.: US 2011/0032686 A1
(43) Pub. Date: Feb. 10, 2011

(54) SERVER CHASSIS WITH COMMON REAR WINDOW FOR ADAPTER AND EXPANSION CARD

(76) Inventor: Te-Chang Lin, San Jose, CA (US)

Correspondence Address: HDLS Patent & Trademark Services, P.O. BOX 220746, CHANTILLY, VA, 20153-0746, US

(21) Appl. No.: 12/535,169

(22) Filed: Aug. 4, 2009

(51) Int. Cl. H05K 7/14

(52) U.S. Cl. 361/801

(57) ABSTRACT

A structure improvement of common rear window for adapter and expansion card, arranged at a bottom seat of a server's chassis and disposed corresponding to a plug-in slot of an inside motherboard at the bottom seat, includes a rear window panel, on which a “U”-shaped notch corresponding to the plug-in slot of the motherboard is arranged, and on an upper edge of which two folded plates are provided, one side of each of which is fixed to the bottom seat, and another side of each of which is extended to an outside of the notch to form a fixing part. Two fixing parts are disposed correspondingly to each other with respect to the notch. A gold finger of a circuit board of the adapter or expansion card is plugged-in the plug-in slot of the motherboard, while a metallically connecting piece of the circuit board is fixed to the two fixing parts.

### BACKGROUND OF THE INVENTION

1. Field of the Invention

The present invention in general relates to a server, in particular, to a server chassis structure with common rear window for an adapter and an expansion card.

2. Description of Prior Art

The position of a server will be different according to the difference of circumstance. In general, a server is so called a “server” is just because it is a machine responsible for managing the things, the files or the web contents needed by a user. For example, a computer for placing the files of a website is called a “website” server, while a server applied in industrial machine or for control management is called an “industrial” server.

The chassis of a traditional server applied in industry mainly includes a front panel, a rear window panel, two lateral plates and a bottom plate located at the bottom, all of which are constituted a square chassis provided for accommodating all kinds of computer hardware, for example, motherboard, power supply, hard disk drive, hard disk and CPU, whereby a server capable of smoothly undergoing a gigantically operational management is thus constructed.

When a server is under assembly, due to the requirement of customer side, it is necessary to install several adapters or expansion cards for the provision of customers to expand or adapt some devices to fulfill the need of each kind of hardware. When assembling these expansion cards or adapters, their assembling positions on the rear window panel are different case by case, because there are different assembling structures for the different expansion cards or adapters. By so doing, specific expansion card or adapter can only be installed at specific rear window panel. Under the circumstance that there are many expansion cards or adapters with different specifications, the manufacturers have to stock many rear window panels of different specifications in order to respond the different kinds of expansion cards or adapters. This drawback causes an increase of manufacturing cost.

Accordingly, after a substantially devoted study, in cooperation with the application of relative academic principles, the inventor has finally proposed the present invention that is designed reasonably to possess the capability to improve the drawbacks of the prior art significantly.

### SUMMARY OF THE INVENTION

Therefore, in order to solve aforementioned problems, the invention is mainly to provide a rear window panel capable of the connection of many kinds of expansion cards and adapters, such that it may significantly reduce the inventory of rear window panels and their manufacturing cost as well.

Secondly, the invention is to provide a structure improvement of common rear window for the adapter and the expansion card, arranged at a bottom seat of a server's chassis and disposed corresponding to a plug-in slot of an inside motherboard at the bottom seat, includes a rear window panel, on which a “U”-shaped notch corresponding to the plug-in slot of the motherboard is arranged, and on an upper edge of which two folded plates are provided, one side of each of which is fixed to the bottom seat, and another side of each of which is extended to an outside of the notch to form a fixing part. Two fixing parts are disposed correspondingly to each other with respect to the notch. A gold finger of a circuit board of the adapter or expansion card is plugged-in the plug-in slot of the motherboard, while a metallically connecting piece of the circuit board is fixed to the two fixing parts.

### BRIEF DESCRIPTION OF DRAWING

The features of the invention believed to be novel are set forth with particularity in the appended claims. The invention itself, however, may be best understood by reference to the following detailed description of the invention, which describes a number of embodiments of the invention, taken in conjunction with the accompanying drawings, in which:

FIG. 1 is an outer perspective illustration of a server according to the present invention;

FIG. 2 is an explosive illustration for the arrangement of the first kind of expansion card according to the present invention;

FIG. 3 is an assembling illustration for the arrangement of the first kind of expansion card according to the present invention;

FIG. 4 is an explosive illustration for the arrangement of the second kind of expansion card according to the present invention;

FIG. 5 is an explosive illustration for the arrangement of the third kind of expansion card according to the present invention;

FIG. 6 is an explosive illustration for the arrangement of the adapter according to the present invention;

FIG. 7 is an illustration of the assembled adapter according to the present invention; and

FIG. 8 is an illustration of the assembled adapter according to the present invention.

### DETAILED DESCRIPTION OF THE INVENTION

In cooperation with attached drawings, the technical contents and detailed description of the present invention are described thereinafter according to a number of preferable embodiments, not used to limit its executing scope. Any equivalent variation and modification made according to appended claims is all covered by the claims claimed by the present invention.

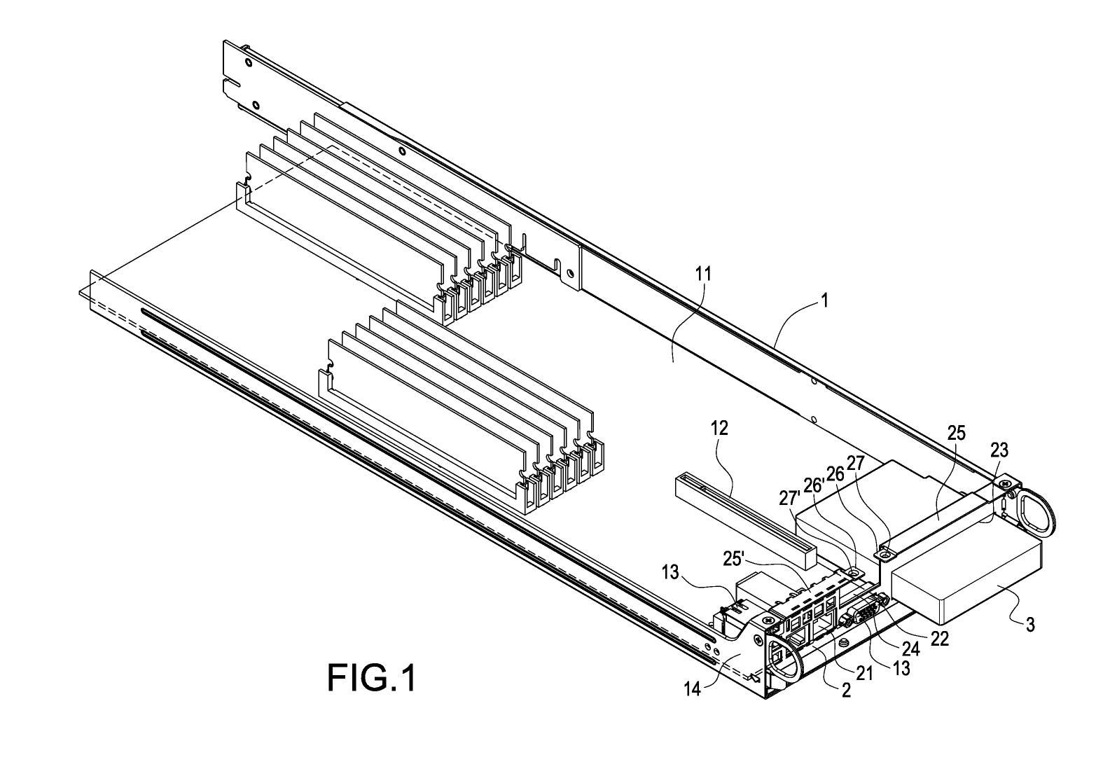

Please refer to FIG. 1, which is an outer perspective illustration of a server according to the present invention. As shown in this figure, a rear window panel 2 is disposed on one side of a bottom seat 1 of the server's chassis. The bottom seat 1 is shown as a “U”-shape, in which a motherboard 11 is disposed. One side of the motherboard 1 is electrically connected at least one plug-in slot 12 shown as a stripe and a plurality of connecters 13 with different specifications. As shown in this figure, the plug-in slot 12 belongs to PCI or PCIE specification.

The rear window panel 2 is assembled at one end side of the bottom seat 1. On the rear window panel 2, a plurality of a first opening 21, a second opening 22, a third opening 23 and a notch 24 shown as a “U”-shape are arranged. The first opening 21 and the second opening 22 correspond to the connectors 13 arranged on the motherboard 11 and having different specifications. The third opening 23 may be provided for a hard disk 3 to be plugged therein and electrically connected to the motherboard 11. In the meantime, the notch 24 corresponds to the plug-in slot 12 on the motherboard 11. In addition, two folded plates 25, 25′ are bent to the outside of the bottom seat 1 from the upper edge of the rear window panel 2. Respectively, one side of each of the two folded plates 25, 25′ is connected fixedly to two lateral plates 14 of the bottom seat 1, while another side is extended to the outside of the notch 24 to be formed into two fixing parts 26, 26′, both of which are disposed correspondingly with respect to the notch 24. Two holes 27, 27′ are formed on the two fixing parts 26, 26 for screws (not shown in the figures) to pass through. Thus, when an adapter or expansion card is installed, a rear window panel 2 can be commonly used.

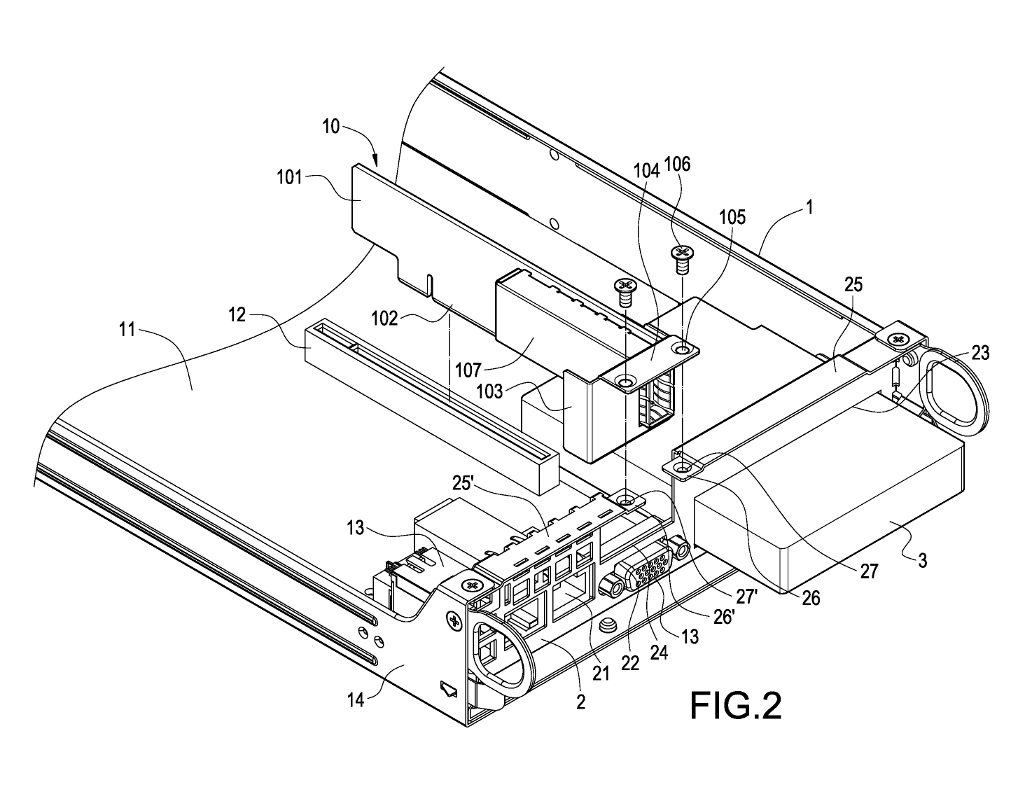

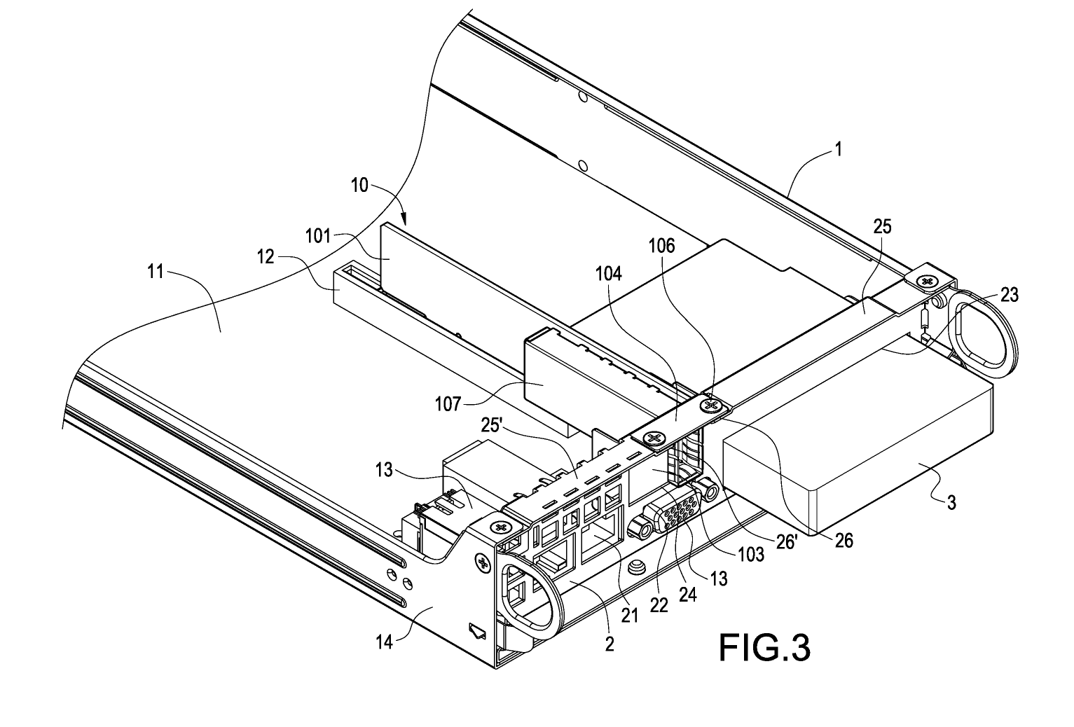

Please refer to FIG. 2 and FIG. 3, which respectively are an explosive illustration and an assembling illustration for the arrangement of the first kind of expansion card according to the present invention. As shown in these two figures, when the first kind of expansion card (IB Card) 10 is installed, the first kind of expansion card 10 has a circuit board 101, a gold finger 102 of which is plugged-in the plug-in slot 12 of the motherboard 11. Furthermore, one side of the circuit board 101 is arranged a metallically connecting piece 103 shown as a “U”-shape, which is disposed corresponding to the notch 24. On the other hand, a fixing piece 104 bent from the lateral edge of the connecting piece 103 is connected by crossing over the two fixing parts 26, 26′ of the two folded plates 25, 25′ with screws 106 passing through two holes 105 of the fixing piece 104 and two holes 27, 27′ of the two fixing parts 26, 26′, such that the first expansion card 10 can be installed into the notch 24 of the rear window panel 2. After the first kind of expansion card 10 is installed, the electric connecters 107 electrically connected to the circuit board 101 can be all connected to the external devices or transmission lines.

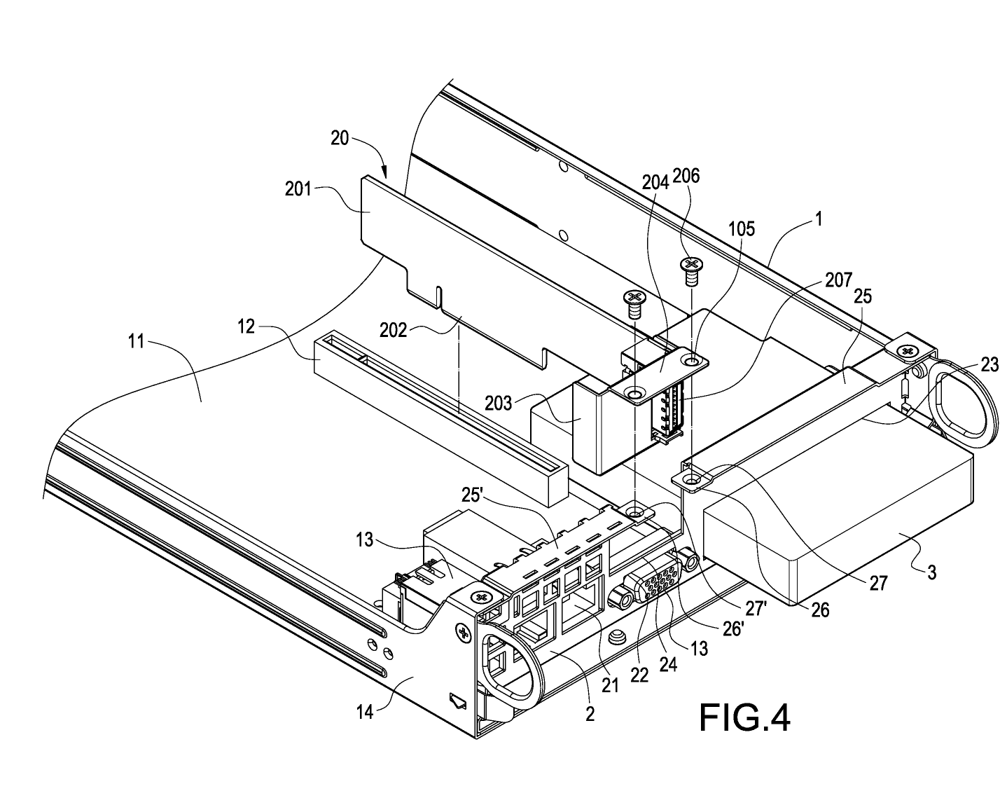

Please refer to FIG. 4, which is an explosive illustration for the arrangement of the second kind of expansion card according to the present invention. As shown in this figure, when the second kind of expansion card (10G Card) 20 is installed, the second kind of expansion card 20 has a circuit board 201, a gold finger 202 of which is plugged-in the plug-in slot 12 of the motherboard 11. Furthermore, one side of the circuit board 201 is arranged a metallically connecting piece 203 shown as a “U”-shape, which is disposed corresponding to the notch 24. On the other hand, a fixing piece 204 bent from the lateral edge of the connecting piece 203 is connected by crossing over the two fixing parts 26, 26′ of the two folded plates 25, 25′ with screws 206 passing through two holes 205 of the fixing piece 204 and two holes 27, 27′ of the two fixing parts 26, 26′, such that the second kind of expansion card 20 can be installed into the notch 24 of the rear window panel 2. After the second kind of expansion card 20 is installed, the electric connecters 207 electrically connected to the circuit board 201 can be all connected to the external devices or transmission lines.

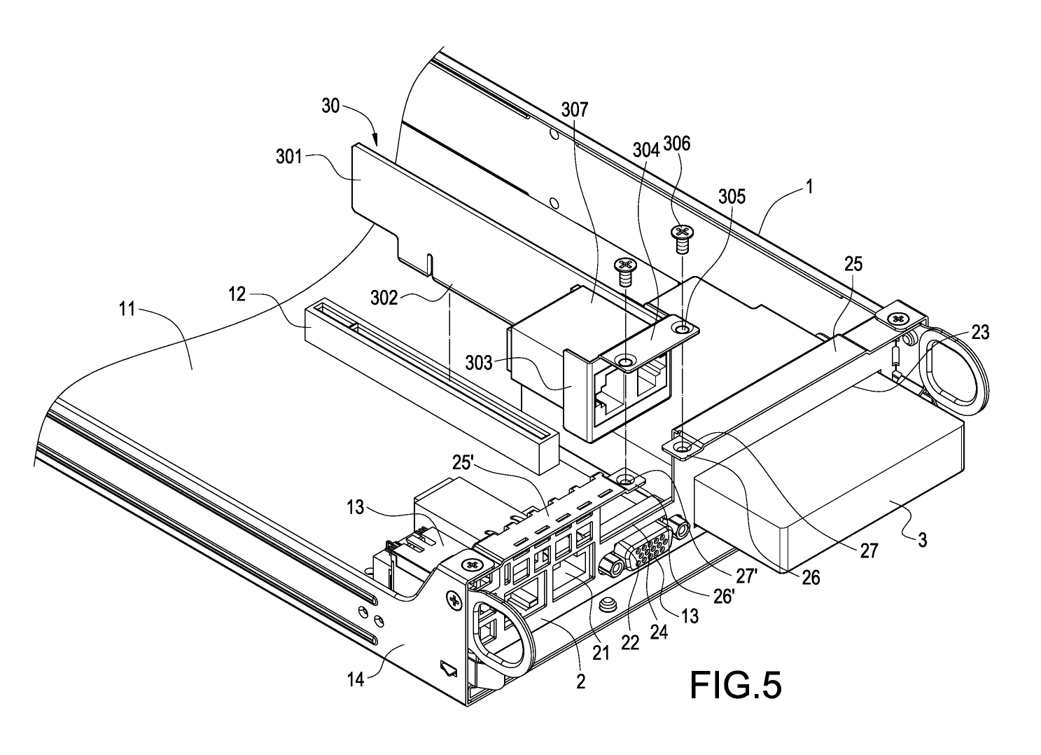

Please refer to FIG. 5, which is an explosive illustration for the arrangement of the third kind of expansion card according to the present invention. As shown in this figure, when the third kind of expansion card (Ethernet Card) 30 is installed, the third kind of expansion card 30 has a circuit board 301, a gold finger 302 of which is plugged-in the plug-in slot 12 of the motherboard 11. Furthermore, one side of the circuit board 301 is arranged a metallically connecting piece 303 shown as a “U”-shape, which is disposed corresponding to the notch 24. On the other hand, a fixing piece 304 bent from the lateral edge of the connecting piece 203 is connected by crossing over the two fixing parts 26, 26′ of the two folded plates 25, 25′ with screws 306 passing through two holes 305 of the fixing piece 304 and two holes 27, 27′ of the two fixing parts 26, 26′, such that the third kind of expansion card 30 can be installed into the notch 24 of the rear window panel 2. After the third kind of expansion card 30 is installed, the electric connecters 307 electrically connected to the circuit board 301 can be all connected to the external devices or transmission lines.

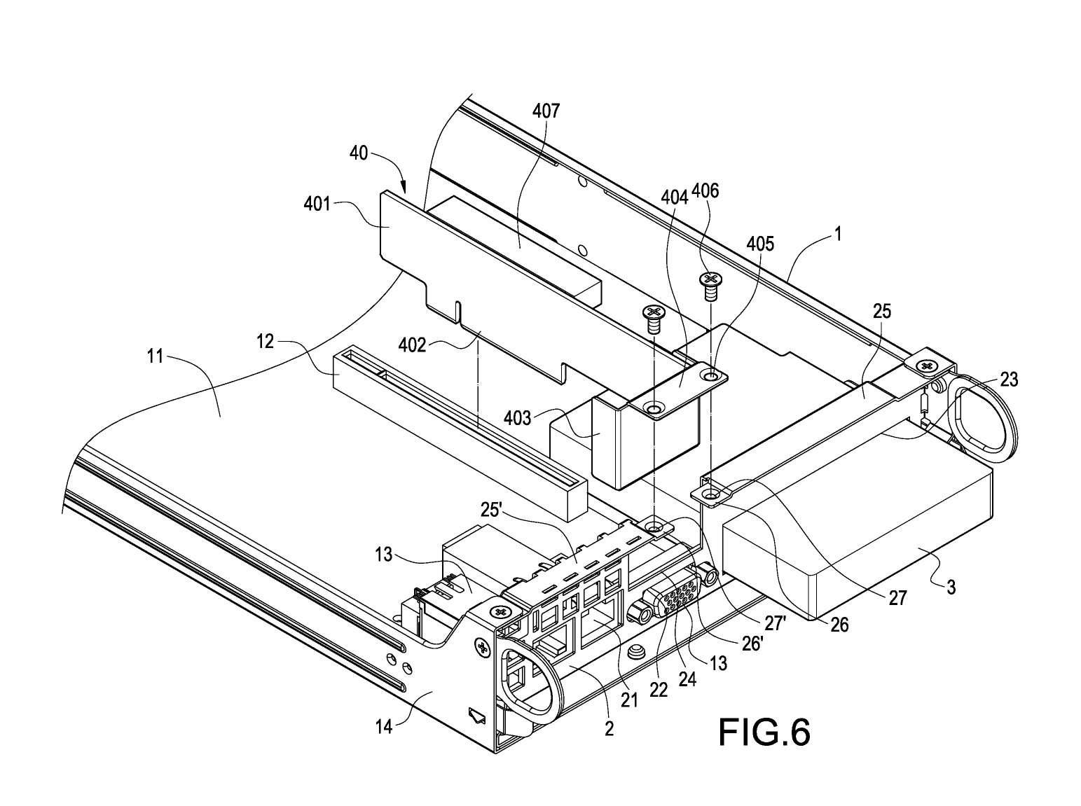

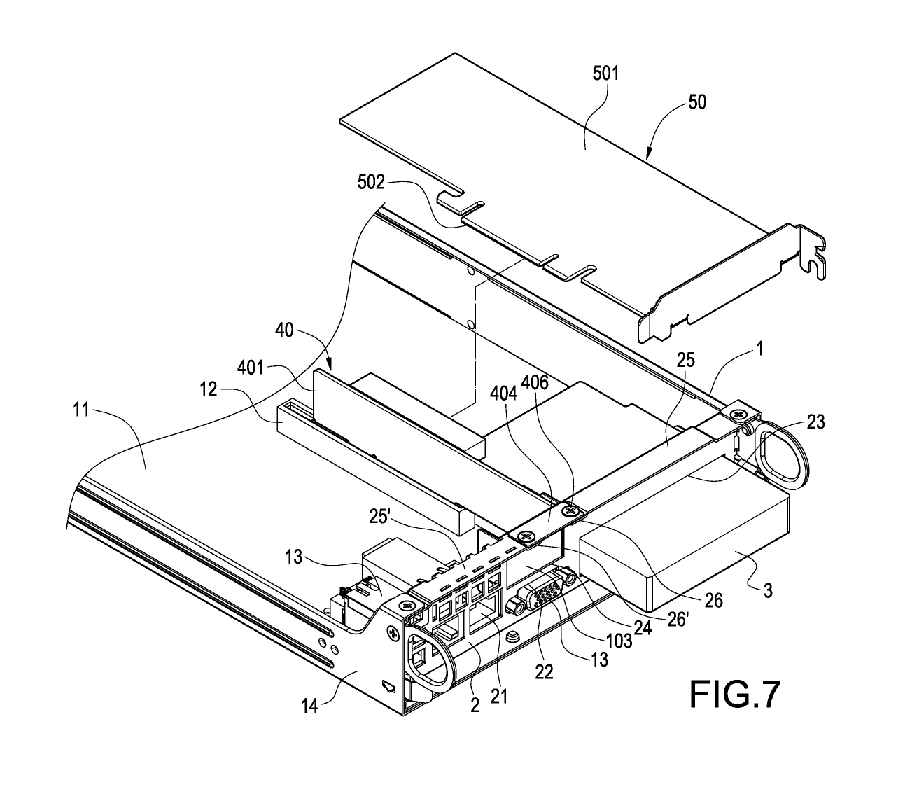

Please refer to FIG. 6 and FIG. 7, which respectively are an explosive illustration and an assembled illustration for the arrangement of the adapter according to the present invention. As shown in these two figures, when the adapter 40 is installed, the adapter 40 has a circuit board 401, a gold finger 402 of which is plugged-in the plug-in slot 12 of the motherboard 11. Furthermore, one side of the circuit board 401 is arranged a metallically connecting piece 403 shown as a “U”-shape, which is disposed corresponding to the notch 24. On the other hand, a fixing piece 404 bent from the lateral edge of the connecting piece 403 is connected by crossing over the two fixing parts 26, 26′ of the two folded plates 25, 25′ with screws 106 passing through two holes 405 of the fixing piece 404 and two holes 27, 27′ of the two fixing parts 26, 26′, such that the adapter 40 can be installed into the notch 24 of the rear window panel 2.

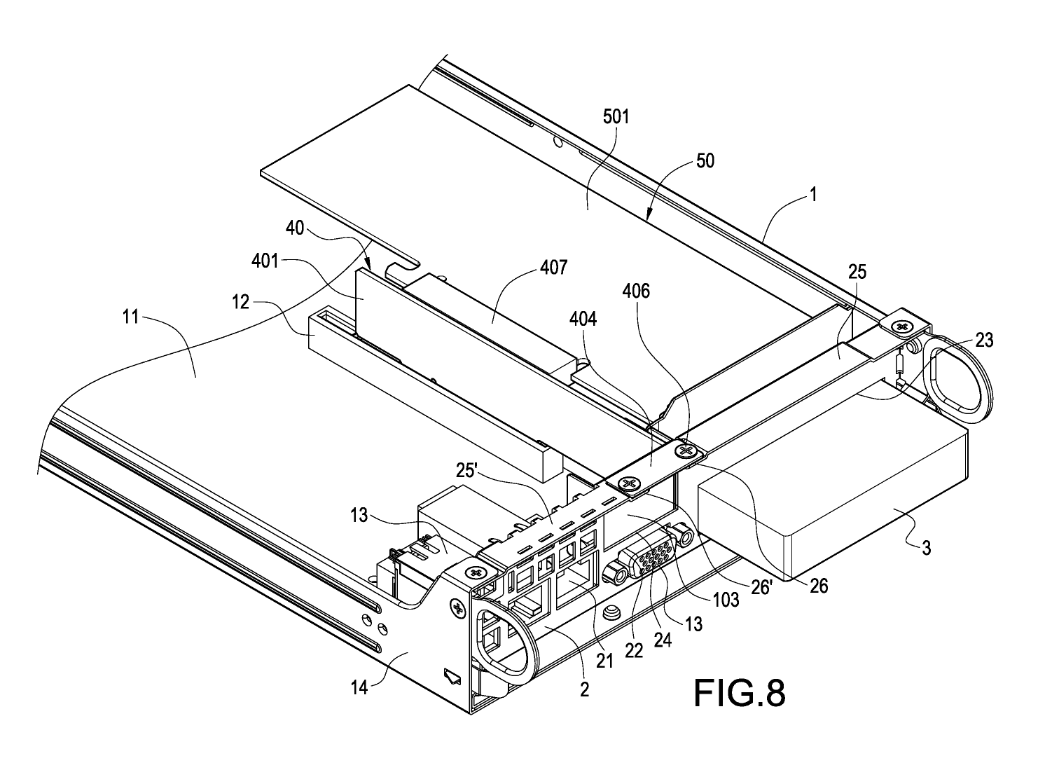

Please refer to FIG. 8, which is an illustration of the assembled adapter according to the present invention. As shown in this figure, after the adapter 40 is installed, an expansion slot 407 is electrically connected onto a circuit board 401 of the adapter 40 and is provided for the fourth kind of expansion card (Standard PCI or PCIE Expansion Card) 50 to be plugged therein. A circuit board 501 of the fourth kind of expansion card 50 has a gold finger 502 to be plugged-in the expansion slot 407 for completing an adaptive arrangement of the fourth kind of expansion card 50.

Accordingly, through the constitution of aforementioned assemblies, a structure improvement of common rear window for adapter and expansion card according to the invention is thus obtained.

Summarizing aforementioned description, the structure improvement of common rear window according to the invention is an indispensably design for an adapter and expansion card indeed, which may positively reach the expected usage objective for solving the drawbacks of the prior arts, and which extremely possesses the innovation and progressiveness to completely fulfill the applying merits of new type patent, according to which the invention is thereby applied. Please examine the application carefully and grant it as a formal patent for protecting the rights of the inventor.

However, the aforementioned description is only a number of preferable embodiments according to the present invention, not used to limit the patent scope of the invention, so equivalently structural variation made to the contents of the present invention, for example, description and drawings, is all covered by the claims claimed thereinafter.

What is claimed is:

1. A structure improvement of common rear window for adapter and expansion card, arranged at a bottom seat of a server's chassis and disposed corresponding to a plug-in slot of an inside motherboard at the bottom seat, including a rear window panel, on which a notch corresponding to the plug-in slot of the motherboard is arranged, and on an upper edge of which two folded plates are provided, one side of each of which is fixed to the bottom seat, and another side of each of which is extended to an outside of the notch to form a fixing part, two fixing parts being disposed correspondingly to each other with respect to the notch.

2. The structure improvement of common rear window according to claim 1, wherein the plug-in slot is any kind of PCI or PCIE.

3. The structure improvement of common rear window according to claim 1, wherein the notch is shown as a “U”-shape.

4. The structure improvement of common rear window according to claim 1, wherein a hole is arranged on each of the two fixing parts.

5. The structure improvement of common rear window according to claim 1, wherein an adjacent place between the real window panel and the notch further includes a first opening, a second opening and a third opening.

6. The structure improvement of common rear window according to claim 5 wherein, at one side of the motherboard adjacent to the plug-in slot, a plurality of connectors of different specifications are electrically connected and are disposed correspondingly to the first and the second openings.

7. The structure improvement of common rear window according to claim 5, wherein the third opening is provided for a hard disk to be inserted therein and electrically connected to the motherboard.

8. The structure improvement of common rear window according to claim 1, further including an expansion card assembled with the motherboard and the rear window panel, the expansion card having a circuit board arranged thereon, the circuit board having a gold finger plugged-in the plug-in slot of the motherboard, one side of the circuit board being arranged a metallically connecting piece shown as a “U”-shape and disposed corresponding to the notch, in addition, a lateral side of the connecting piece being bent into a fixing piece connected by crossing over the two fixing parts of the two folded plates with two screws passing through two holes of the fixing piece and two holes of the two fixing parts, furthermore, an electric connector being electrically connected onto the circuit board.

9. The structure improvement of common rear window according to claim 1, wherein further including an adapter assembled with the motherboard and the rear window panel, the adapter having a circuit board arranged thereon, the circuit board having a gold finger plugged-in the plug-in slot of the motherboard, one side of the circuit board being arranged a metallically connecting piece shown as a “U”-shape and disposed corresponding to the notch, in addition, a lateral side of the connecting piece being bent into a fixing piece connected by crossing over the two fixing parts of the two folded plates with two screws passing through two holes of the fixing piece and two holes of the two fixing parts.

10. The structure improvement of common rear window according to claim 9, wherein an expansion slot is electrically connected onto the circuit board of the adapter.
